(19) United States
(12) Patent Application Publication
(10) Pub. No.: US 2005/0127931 A1
(43) Pub. Date: Jun. 16, 2005

(54) Variable temperature test cell and associated method

(76) Inventors: Robert L. Karlinsey JR., Bloomington, IN (US); John P. Carini, Bloomington, IN (US)

Correspondence Address: BARNES & THORNBURG, 11 SOUTH MERIDIAN, INDIANAPOLIS, IN, 46204, US

(21) Appl. No.: 10/733,673

(22) Filed: Dec. 11, 2003

(51) Int. Cl. G01R 31/02

(52) U.S. Cl. 324/760

(57) ABSTRACT

A test cell for testing the electrochemical properties of a solid-state test specimen is herein disclosed. The test cell includes a heating element operable to increase the temperature of the test specimen to a desired temperature. A method of testing the electrochemical properties of a solid-state specimen is also disclosed.

### SPONSORSHIP

Work on this invention was sponsored by the National Science Fund Grant No. DMF-9870246 and National Aeronautics and Space Administration Grant No. NAG3-2588. The government has certain rights in this invention.

### FIELD OF THE DISCLOSURE

The present disclosure relates generally to test cells for testing the electrochemical properties of a solid-state specimen such as a polymer or inorganic glass.

### BACKGROUND OF THE DISCLOSURE

Solid-state materials such as clay, ceramic, inorganic glass, silicon, polymers and the like are developed for a large number of industrial applications. During development, it is often desirable to determine the electrochemical properties (e.g., dielectric constant or electrical conductivity) of the material. For example, impedance spectroscopy may be utilized to determine the electrical conductivity of a material.

During testing of a solid-state material, it is often necessary to subject the material to a wide range of temperatures to determine the behavior of the material in different conditions. For example, to test a solid-state material at elevated temperatures, the material is placed in a large oven, heated to the desired temperature, and tested. The material may be positioned in a test jig or cell when positioned in the oven. In certain systems, the material may be tested while positioned in the oven.

### SUMMARY OF THE DISCLOSURE

According to one aspect of the disclosure, a test cell includes an integrated heating assembly. In a specific exemplary implementation, a heating element is secured to a housing of the test cell. The heating element may be embodied as a number of resistors which heat the housing, and hence the test specimen positioned therein, upon the application of electrical current to the resistors.

The heating element is electrically coupled to a controller which operates the heating element to generate a desired amount of heat. In the case of the heating element embodied as a number of heat generating resistors, the controller may be embodied as an R/G bridge which supplies a controlled current to the resistors to generate the desired amount of heat.

The test cell may include a temperature sensor to determine the temperature of the test specimen. The temperature sensor may be used as part of a closed-loop control scheme to maintain the test specimen at a desired temperature. The temperature sensor may be embodied as a platinum resistor secured to a sample support plate on which the test specimen is positioned.

The housing of the test cell may be constructed of a thermally conductive metal such as aluminum or copper.

The test cell may include a sample support assembly positioned in the housing. In an exemplary implementation, the sample support assembly includes a pair of electrodes, each of which is secured to a metallic support plate. Each of the electrodes is electrically coupled to an impedance meter which is operable to measure electrical characteristics of the test specimen (e.g., electrical impedance).

The test cell may also include a number of metallic rods which are secured to the housing's cap. A portion of the metallic rods is positionable in a cooling bath, such as a nitrogen bath, to cool the test specimen to a desired temperature.

According to another aspect of the disclosure, a method of testing a solid-state specimen includes the steps of positioning the solid-state specimen in a housing of a test cell, and applying an electrical current to a number of resistors secured to the housing to heat the housing.

The electrical current may be adjusted based on output from a temperature sensor to maintain the specimen at a desired temperature.

Electrochemical properties of the specimen may be measured while the specimen is maintained at a desired temperature.

### BRIEF DESCRIPTION OF THE DRAWINGS

FIG. 1 is a cross sectional view of a test cell for testing the electrochemical properties of a solid-state specimen, note that a number of the components are not shown in cross section for clarity of description;

FIG. 2 is a top view of the test cell of FIG. 1 with the cap and upper sample plate removed; and

FIG. 3 is a fragmentary view of the test cell of FIG. 1 showing the test cell in an inverted position with its metallic cooling rods extending into a cooling bath.

### DETAILED DESCRIPTION OF THE DRAWINGS

While the concepts of the present disclosure are susceptible to various modifications and alternative forms, specific exemplary embodiments thereof have been shown by way of example in the drawings and will herein be described in detail. It should be understood, however, that there is no intent to limit the disclosure to the particular forms disclosed, but on the contrary, the intention is to cover all modifications, equivalents, and alternatives following within the spirit and scope of the invention as defined by the appended claims.

Referring now to the drawings, there is shown a test cell 10 for use in testing the electrochemical properties of a solid-state materials such as clay, ceramic, inorganic glass, silicon, polymers and the like. The test cell 10 includes a housing 12 having a cap 14 and a base 16 secured thereto. Illustratively, the cap 14 and the base 16 are secured to the housing 12 with threaded fasteners such as screws 18. In the exemplary embodiment described herein, the housing 12, the cap 14, and the base 16 are each constructed of a metallic material such as aluminum or copper.

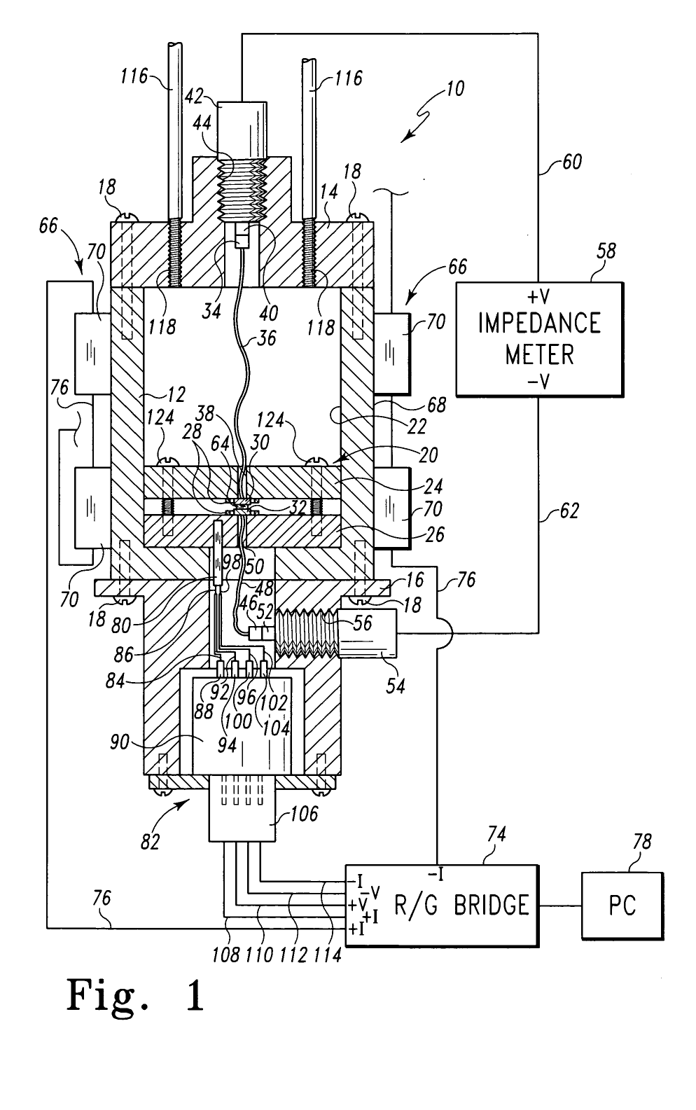

As shown in FIG. 1, the housing 12 defines a cavity 22. A sample support assembly 20 is positioned in the cavity 22. The sample support assembly 20 includes an upper sample plate 24 and a lower sample plate 26. The sample plates 24, 26 are illustratively constructed of aluminum. A nylon or fiberglass washer 28 is secured to each of the sample plates 24, 26.

The sample support assembly 20 also includes a pair of electrodes. In the exemplary embodiment described herein, an upper electrode 30 is positioned on the upper sample plate 24, and a lower electrode 32 is positioned on the lower sample plate 26. The electrodes 30, 32 may be embodied as any type of electrical contact. In the exemplary embodiment described herein, the electrodes 30, 32 are embodied as copper discs.

The upper electrode 30 is coupled to a female connector 34 via a wire 36 which extends through a bore 38 defined in the upper sample plate 24. A mating male connector 40 is soldered or otherwise connected to an external connector 42. In the exemplary embodiment described herein, the connector 42 is embodied as a BNC connector which is threaded into a threaded bore 44 defined in the cap 14.

Likewise, the lower electrode 32 is coupled to a female connector 46 via a wire 48 which extends through a bore 50 defined in the lower sample plate 26. A mating male connector 52 is soldered or otherwise connected to an external socket 54. As with the connector 42, in the exemplary embodiment described herein, the connector 54 is also embodied as a BNC connector. The connector 54 is threaded into a threaded bore 56 defined in the base 16.

The above-described configuration allows for ease of removal of the components of the sample support assembly 20. For example, to remove the sample support assembly 20 from the housing 12, the male connector 40 may be disconnected from the female connector 34 thereby allowing the wire 36 to be separated from the BNC connector 42. Similarly, the wire 48 may be separated from the BNC connector 54 by disconnecting the connectors 46, 52 from one another thereby allowing the lower plate 26 to be separated from the housing 12.

As shown in FIG. 1, the BNC connectors 42, 54 are electrically coupled to an impedance meter 58. Specifically, one end of a cable 60 is coupled to the BNC connector 42 with the other end of the cable 60 being coupled to the impedance meter 58. A first end of a cable 62 is coupled to the BNC connector 54, with the other end being coupled to the impedance meter 58. In such a way, the impedance meter 58 may be used to measure the electrical conductivity of a test specimen 64 positioned between the electrodes 30, 32. The impedance meter 58 is configured to provide a test voltage to measure the impedance across the specimen 64. In the case of impedance spectroscopy, the meter 58 may take numerous measurements at various frequencies. One impedance meter which may be used as the impedance meter 58 is a model number HP4192A Impedance Meter which is commercially available from Hewlett-Packard Company of Palo Alto, Calif.

The test cell 10 also includes a heating element 66. As used herein, the term “heating element” is intended to mean any component or assembly that transforms fuel or electricity into heat. As shown in FIG. 1, the heating element 66 is coupled to the housing 12. In the specific exemplary embodiment described herein, the heating element 66 is secured to an outer surface 68 of the housing 12. It should be appreciated that the heating element 66 may be coupled to the housing by securing it directly to the housing 12, or, alternatively, a number of thermally conductive spacers (not shown) may be positioned between the heating element 66 and the housing 12.

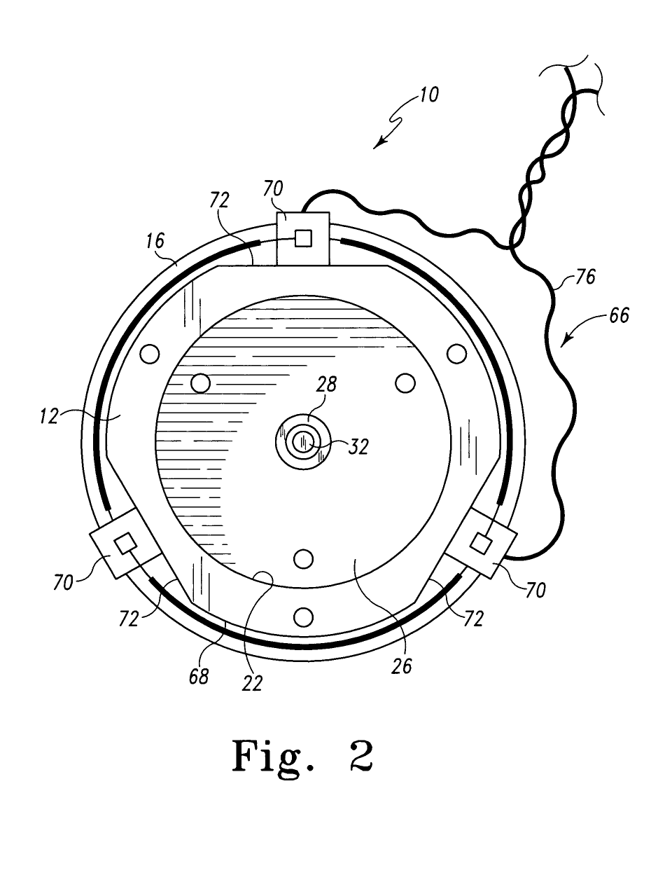

In the specific exemplary embodiment described herein, the heating element 66 is embodied as a number of wire-wound power resistors 70. Each of the resistors 70 is secured to the outer surface 68 of the housing. Specifically, as shown in FIG. 2, the outer surface 68 of the housing 12 has three flats 72 defined therein. Two of the resistors 70 are secured to each of the flats 72.

The power resistors 70 may be embodied as any type of resistor which generates suitable amounts of heat when a current is applied thereto. One such resistor which may be used as the power resistor 70 is a part number RER60F127 OM, 5 Watt, 127 Ω, 1% tolerance wire-wound power resistor which is commercially available from Vishay Intertechnology, Inc. of Malvern, Pa. In an exemplary arrangement, six (6) of such resistors are arranged in a parallel combination of two sets of three resistors in series to yield a total resistance of 190.5 Ω.

The resistors 70 may be utilized to heat the test specimen 64 to a desired temperature. In particular, when an electrical current is applied to the resistors 70, the resistors generate significant amounts of thermal energy (i.e., heat). Such heat is transferred to the outer surface 68 of the housing 12 to heat the housing and hence the test specimen 64 positioned in the sample support assembly 20 via a thermal path which includes the housing 12 and the sample plates 24, 26.

The resistors 70 are electrically coupled to a current source 74 via a number of twisted pair cables 76. In the exemplary embodiment described herein, the current source 74 is embodied as an R/G bridge. As such, a desired electrical current may be applied and maintained on the resistor circuit. On such R/G bridge which may be used is a model number 1802 Digital R/G Bridge which is commercially available from Quantum Design of San Diego, Calif.

A personal computer (PC) 78 is interfaced with the R/G bridge 74. The PC 78 is operable to execute a desired control routine for testing the specimen at desired parameters. For example, the PC 78 may operate the R/G bridge 74 to generate a desired current to produce a desired specimen temperature profile. Specifically, by varying the current applied to the resistors 70, the amount of heat generated by the resistors 70 may be varied. The PC 78 may be programmed to execute predetermined test routines which allow the test specimen 64 to be tested at various temperature profiles.

The test cell 10 includes a temperature sensor 80. The temperature sensor 80 is utilized to determine the temperature of the test specimen 64 positioned between the electrodes 30, 32. In the exemplary embodiment described herein, the temperature sensor 80 is secured to the lower sample plate 26. As such, the temperature sensor 80 senses the temperature of the sample plate 26 which is indicative of, or may be correlated to, the temperature of the test specimen 64. It should be appreciated that the temperature sensor 80 may be located in any number of locations to determine the temperature of the test specimen 64, with the embodiment described herein (i.e., secured to the sample plate 26) being merely exemplary in nature.

As described herein, the temperature of the test specimen 64 is determined indirectly. In particular, as described above, the temperature of the sample plate 26 is sensed by the temperature sensor 80 and used as an indicator of the temperature of the test specimen 64. Calculations may be performed to account for the use of such an indirect temperature measurements, if desired. Alternatively, the output from such an indirect temperature measurement may be extrapolated to a corresponding direct specimen temperature or otherwise adjusted. In other words, the herein described methods and systems may be configured to accommodate for the use of indirect temperature measurements of the test specimen 64.

It should be appreciated that a temperature sensor could be utilized to sense the temperature of the test specimen 64 directly, if desired. As used herein, references to “determining” or “to determine” the temperature of the test specimen are intended to mean the use of either direct or indirect temperature measurements.

In the exemplary embodiment described herein, the temperature sensor 80 is embodied as a platinum resistor. The platinum resistor 80 is electrically coupled to the R/G bridge 74 via a connector assembly 82. Specifically, a wire 84 is soldered on one end to a first lead 86 of the platinum resistor 80, whereas a second end of the wire 84 is soldered to a first pin 88 of a male connector 90 of the connector assembly 82. A wire 92 is soldered on one end to the first lead 86 of the platinum resistor 80, with a second end of the wire 92 being soldered to a second pin 94 of the male connector 90. A wire 96 is soldered on one end to a second lead 98 of the platinum resistor 80, whereas a second end of the wire 96 is soldered to a third pin 100 of the male connector 90. A wire 102 is soldered on one end to the second lead 98 of the platinum resistor 80, with a second end of the wire 102 being soldered to a fourth pin 104 of the male connector 90.

A female connector 106 is coupled to the male connector 90. The interface pins of the male connector 90 and the corresponding receptacles of the female connector 106 electrically couple the pins 88, 94, 100, 104 to the first end of a number of wires 108, 110, 112, 114, respectively. A second end of each of the wires 108, 110, 112, 114 is coupled to the R/G bridge 74.

The R/G bridge uses one of the electrical connections to the first lead 86 of the platinum resistor 80 and one of the electrical connections from the second lead 98 of the platinum resistor 80 to measure the resistance of the resistor 80. For example, the R/G bridge 74 may be used to provide a test voltage of a given value across the platinum resistor 80 to determine the resistance thereof. The platinum resistor's resistance changes as a function of the temperature of the resistor 80. As such, by monitoring the resistance of the platinum resistor 80, the temperature of the sample plate 26 may be determined which, as described above, is indicative of the temperature of the test specimen 64.

It should be appreciated that use of the platinum resistor 80 provides the feedback portion of a closed-loop control scheme. In particular, the electrical current applied to the power resistors 70 may be varied in response to output from the platinum resistor 80. Indeed, as described above, the amount of heat generated by the power resistors 70 may be varied by varying the current applied thereto. As such, the sensed temperature from the platinum resistor 80 may be used by the control routine to adjust the current supplied to the power resistors 70 to achieve and maintain a desired temperature within the housing 12.

The R/G bridge uses the second electrical connection to the first lead 86 of the platinum resistor 80 and the second electrical connection from the second lead 98 of the platinum resistor 80 to selectively apply current to the platinum resistor 80. In certain embodiments, it may be desirable to warm the test specimen “locally.” It should be appreciated that if a given design of a test cell does not utilize such “local” warming of the test specimen, only a single pair of wires (for measuring resistance of the resistor 80 as described above) need be connected to the platinum resistor 80.

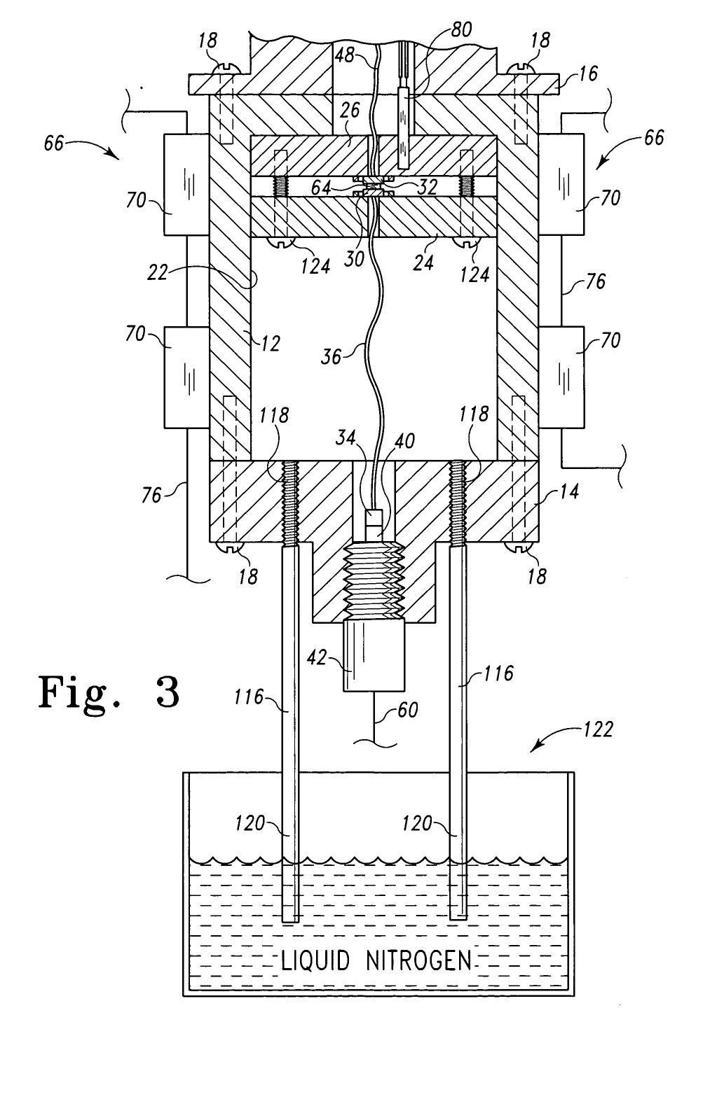

As shown in FIG. 3, the test cell 10 also includes a number of cold-sink members 116. In the exemplary embodiment described herein, the cold-sink members 116 are embodied as a number of metallic rods which are threaded into the cap 14. Illustratively, the metallic rods 116 may be constructed with copper, although other metallic material may be used as well. One end 118 of the metallic rods 116 is threaded into the cap 14, whereas the other end 120 extends outwardly from the cap 14.

As shown in FIG. 3, the outer end 120 of the metallic rods 116 may be positioned in a cooling bath 122 such as a dewar flask of liquid nitrogen. In such a way, the metallic rods 116 provide a thermal pathway from the cooling bath 122 to the housing 12. Use of the metallic rods 116 and the cooling bath 122 allows the test specimen 64 to be cooled to relatively low temperatures (e.g., −100° C.).

In operation, the test cell 10 may be used to measure the electrical properties of the solid-state test specimen 64. To do so, the test specimen 64 is first positioned in the sample support assembly 20. Specifically, the test specimen 64 is positioned between the electrodes 30, 32. Both of the sample plates 24, 26 may be removed from the housing 12 during such assembly. Alternatively, the lower sample plate 26 may remain in the cavity 22 of the housing 12 during specimen loading. In such a case, the specimen 64 is positioned on the lower electrode 32. Thereafter, the upper plate 24 is lowered into the sample cavity 22 such that the upper electrode 30 is urged into contact with the sample specimen 64 thereby sandwiching the specimen 64 between the electrodes 30, 32. A number of screws 124 are then installed to secure the sample plates 24, 26 to one another. Use of the screws enhances contact between the electrodes 30, 32 and the specimen 64.

Once the specimen 64 has been secured between the electrodes 30, 32, the cap 14 may be installed. To do so, the female connector 34 is first connected to the mating male connector 40 to electrically couple the upper electrode 30 (and hence the specimen 64) to the BNC connector 42. Thereafter, the threaded holes in the cap 14 are aligned with the corresponding holes in the housing 12 and the screws 18 are inserted therein to secure the cap 14 to the housing 12. If the test procedure to be performed requires cooling of the test specimen 64, the metallic rods 116 are threaded into their respective holes in the cap 14.

If not already done, the BNC connector 42 is then coupled to the impedance meter 58 by use of the cable 60, and the BNC connector 54 is coupled to the impedance meter 58 by use of the cable 62. Likewise, if not already done, the power resistors 70 are coupled to the appropriate connectors of the R/G bridge 74 by use of the twisted pair cables 76. Moreover, if not already done, the female connector 106 is then connected to the male connector 90 to electrically couple the platinum resistor 80 to the R/G bridge 74.

Once the test cell 10 has been assembled and coupled to the impedance meter 58 and the R/G bridge 74, testing of the electrochemical properties of the test specimen 64 may commence. For example, the electrical conductance of the test specimen 64 may be measured as the specimen is subjected to wide temperature range such as −40° C. to 40° C., although other temperature ranges (e.g., −100° C. to 80° C.) are possible. To do so, the test cell 10 is first inverted, and the metallic rods 116 are inserted into the liquid nitrogen cooling bath 122 thereby cooling the specimen 64. The output of the platinum resistor 80 may be monitored to determine the temperature of the specimen 64. Once the specimen 64 reaches a desired temperature (e.g., −40° C.), the impedance meter 58 may be operated to obtain conductance measurements of the specimen 64 across a wide range of frequencies.

The temperature of the cell 10 and hence the test specimen 64 may then be raised at a predetermined rate. The temperature of the test specimen 64 may be raised by reducing the exposure of the test cell 10 to the cooling bath 122, actuation of the heating element 66, or a combination of both. During such raising of the temperature of the specimen 64, the impedance meter 58 begins to develop a spectrum by continuing to measure conductance of the test specimen 64 across a wide range of frequencies.

If not already actuated, the heating element 66 is used to elevate the temperature of the specimen to a desired endpoint (e.g., 40° C.). Specifically, the R/G bridge 74 applies a current to the power resistors 70 thereby causing the resistors 70 to generate heat. The heat is transferred to the housing 12 and hence the specimen 64. The output from the platinum resistor 80 is indicative of the temperature of the specimen 64, and is used as a feedback mechanism to allow the temperature of the specimen 64 to be raised in a controlled manner. As the temperature increases, the impedance meter 58 continues to develop the spectrum by measuring the conductance of the test specimen 64 across a wide range of frequencies.

It should be appreciated that the above procedure may be used to test the specimen 64 across a relatively wide temperature range. Time vs. temperature profiles may be developed based on the design of a specific procedure. Such profiles may be programmed using appropriate software resident on the PC 78 to operate the R/G bridge 74 to produce a desired environment within the test cell 10.

While the concepts of the present disclosure have been illustrated and described in detail in the drawings and foregoing description, such an illustration and description is to be considered as exemplary and not restrictive in character, it being understood that only the illustrative embodiments have been shown and described and that all changes and modifications that come within the spirit of the disclosure are desired to be protected.

There are a plurality of advantages of the concepts of the present disclosure arising from the various features of the apparatus and methods described herein. It will be noted that alternative embodiments of each of the apparatus and methods of the present disclosure may not include all of the features described yet still benefit from at least some of the advantages of such features. Those of ordinary skill in the art may readily devise their own implementations of an apparatus and method that incorporate one or more of the features of the present disclosure and fall within the spirit and scope of the invention as defined by the appended claims.

For example, although the power resistors 70 are herein described as being secured to the outer surface 68 of the housing 12, it should be appreciated that the power resistors 70 could be arranged in any desired arrangement that allows for the transfer of heat to the test specimen 64. For instance, the power resistors 70 may be secured to an inner surface of the housing 12. Alternatively, the power resistors 70 may be secured to the sample plates 24, 26. Moreover, the test cell 10 could be constructed with additional structures to which the resistors 70 may be secured. The power resistors 70 may be secured to any structure that can provide a thermal path (or a portion of a thermal path) to the test specimen 64.

1. A test cell for solid-state specimens, comprising:
a housing,
a pair of electrodes positioned in the housing, and
a heating element coupled to the housing.

2. The test cell of claim 1, wherein:
the housing has (i) an outer surface, and (ii) a cavity,
the pair of electrodes is positioned in the cavity, and
the heating element is secured to the outer surface.

3. The test cell of claim 1, wherein the heating element is secured to an outer surface of the housing.

4. The test cell of claim 3, wherein:
the housing is cylindrical in shape with a flat defined in the outer surface thereof, and
the heating element is secured to the flat.

5. The test cell of claim 1, wherein the heating element comprises a resistor.

6. The test cell of claim 5, wherein the resistor is secured to an outer surface of the housing.

7. The test cell of claim 5, wherein:
the resistor is coupled to a current source, and
the resistor is configured to generate heat which is transferred to the housing upon application of current from the current source.

8. The test cell of claim 1, wherein the heating element comprises a plurality of resistors.

9. The test cell of claim 8, wherein each of the plurality of resistors is secured to an outer surface of the housing.

10. The test cell of claim 8, wherein each of the plurality of resistors is (i) coupled to a current source, and (ii) configured to generate heat which is transferred to the housing upon application of current from the current source.

11. The test cell of claim 1, further comprising a temperature sensor positioned to determine the temperature of a test specimen positioned between the pair of electrodes.

12. The test cell of claim 11, wherein the temperature sensor comprises a platinum resistor.

13. The test cell of claim 1, further comprising:
a cap secured to an open end of the housing, and
a cold-sink member secured to the cap.

14. The test cell of claim 13, wherein the cold-sink member comprises a metallic rod.

15. The test cell of claim 1, wherein the housing is metallic.

16. A test system for solid-state specimens, comprising a test cell having (i) a first electrode, (ii) a second electrode, and (iii) a heating element operable to heat a test specimen positioned between the first electrode and the second electrode.

17. The test system of claim 16, further comprising a current source, wherein the heating element comprises a resistor electrically coupled to the current source.

18. The test system of claim 17, wherein:
the test cell further comprises a housing having an outer surface and a cavity,
the first electrode and the second electrode are positioned in the cavity, and
the resistor is secured to the outer surface.

19. The test system of claim 17, wherein:
the test cell further comprises a housing, and
the resistor is secured to an outer surface of the housing.

20. The test system of claim 19, wherein:
the housing is cylindrical in shape with a flat defined in the outer surface thereof, and
the resistor is secured to the flat.

21. The test system of claim 17, wherein the current source comprises an R/G bridge.

22. The test system of claim 16, further comprising a current source, wherein the heating element comprises a plurality of resistors electrically coupled to the current source.

23. The test system of claim 22, wherein:
the test cell further comprises a housing, and
each of the plurality of resistors is secured to an outer surface of the housing.

24. The test system of claim 16, wherein the test cell further comprises a temperature sensor positioned to determine the temperature of the test specimen.

25. The test system of claim 24, wherein the temperature sensor comprises a platinum resistor.

26. The test system of claim 16, further comprising a cooling bath, wherein the test cell further comprises:
a housing,
a cap secured to an open end of the housing, and
a cold-sink member having a first end which is positionable in the cooling bath and a second end secured to the cap.

27. The test system of claim 26, wherein the cold-sink member comprises a metallic rod.

28. The test system of claim 16, further comprising an impedance meter electrically coupled to the first electrode and the second electrode.

29. A test cell for solid-state specimens, comprising:
a housing, and
a plurality of resistors coupled to the housing.

30. The test cell of claim 29, wherein:
the housing has (i) an outer surface, and (ii) a cavity,
a test specimen is positionable in the cavity, and
the plurality of resistors are secured to the outer surface.

31. The test cell of claim 29, wherein:
the housing is cylindrical in shape with a plurality of flats defined in the outer surface thereof, and
the plurality of resistors are secured to the plurality of flats.

32. The test cell of claim 29, wherein the plurality of resistors are configured to generate heat which is transferred to the housing upon application of current from a current source.

33. The test cell of claim 29, further comprising a temperature sensor positioned to determine the temperature of a test specimen positioned in the housing.

34. The test cell of claim 33, wherein the temperature sensor comprises a platinum resistor.

35. The test cell of claim 29, further comprising:
a cap secured to an open end of the housing, and
a cold-sink member secured to the cap.

36. The test cell of claim 35, wherein the cold-sink member comprises a metallic rod.

37. The test cell of claim 29, wherein the housing is metallic.

38. A method of testing a solid-state specimen, the method comprising the steps of:
positioning the solid-state specimen in a housing of a test cell, and
applying an electrical current to a number of resistors secured to the housing to heat the housing.

39. The method of claim 38, wherein the positioning step comprises positioning the solid-state specimen between a first electrode and a second electrode.

40. The method of claim 39, wherein the positioning step further comprises coupling the first electrode and the second electrode to an impedance meter.

41. The method of claim 38, further comprising the step of sensing the temperature of the test specimen with a temperature sensor.

42. The method of claim 41, wherein the applying step comprises adjusting the electrical current applied to the resistor based on output from the temperature sensor.
